(19) United States
(12) Patent Application Publication
(10) Pub. No.: US 2006/0268523 A1
(43) Pub. Date: Nov. 30, 2006

(54) Heat sink for memory

(75) Inventor: Chuan Hung Lin, HsinChuang City (TW)

Correspondence Address: TROXELL LAW OFFICE PLLC, SUITE 1404, 5205 LEESBURG PIKE, FALLS CHURCH, VA, 22041, US

(73) Assignees: Akust Technology Co., Ltd.; Abesta International Co., Ltd.

(21) Appl. No.: 11/184,877

(22) Filed: Jul. 20, 2005

(30) Foreign Application Priority Data
May 31, 2005 (TW) 094209020

(51) Int. Cl. H05K 7/20

(52) U.S. Cl. 361/710

(57) ABSTRACT

This invention relates to an improved heat sink for memory, it comprising of two clamp pieces and a fixing plug, especially, the two clamp pieces are symmetrical to each other, there are all kinds of dented and bumped interleaved special marks installed on their outer surfaces along flow field direction, moreover, corresponding dented and protruding pivoting parts are installed at two sides of one side of their corresponding inner surfaces, through the two dented and protruding pivoting parts and the fixing plug to penetrate and lock them, an inverted U shape heat sink structure is thus formed; therefore, when is in use, in addition to possessing easy and convenient assembly, there is no need to have the assistance from other support tool for the assembly of the heat sink and memory in the production line, it is only needed to embed the memory and touch it all the way to the lower ends of the dented and protruding pivoting parts to achieve accurate positioning function, meanwhile, the two clamp pieces will not get distorted, they can limit the memory to perform movement only in single direction, therefore, heat sink and memory can accurately touch and position each other to achieve good heat dissipating effect and to have the heat dissipating efficiency enhanced.

### BACKGROUND OF THE INVENTION

1. Field of the Invention

An improved heat sink for memory, it uses a set of symmetrical clamp pieces and dented and bumped interleaved special marks installed on the corresponding outer side surfaces, as well as the corresponding dented and protruding pivoting parts installed at both ends of one side of the corresponding inner surface, moreover, fixing plug is used to penetrate and combine the whole design into one piece in order to achieve better heat-dissipating effect and the heat-dissipating efficiency.

2. Description of the Prior Art

The heat sink structure specifically used for the memory is as shown in Taiwan's, patent No. 415598 “A heat sink structure for random access memory”, No. 422490 “An improved heat sink structure for random access memory”, etc., they disclose the design of using screw locking method to clamp memory in between two piece type head-dissipating board; moreover, patent No. 495101 “Heat dissipating structure for memory”, No. M256523 “Assisted heat dissipating device for memory”, etc., they disclose the technology of a clamp component having special design to clamp simultaneously the memory and two pieces of heat sinks into one piece.

No matter what structures or improvements as mentioned above, their final purpose is to enhance the heat dissipating efficiency of the memory in order to keep its stability of continuous operation and lengthen its lifetime of usage. However, under the severe competition environment, a product with more features and functions will eventually acquire the attention from customers and trigger their purchasing desire, therefore, how to develop product of better, more compact, multiple-element oriented nature and product that considering human nature will no doubt bring in large business opportunity, it is for sure one of the key topics that most of the companies in this business want to invest on its R&D.

Therefore, the inventor of the current invention, based on professional knowledge and experiences of many years, has spent so much efforts on testing and improving and finally has the creation of the current invention “An improved heat sink for memory”.

### SUMMARY OF THE INVENTION

The main purpose of the current invention is to provide an improved heat sink for memory, it uses a set of symmetrical clamp pieces and uses the corresponding dented and pivoting part installed on both ends of one side of their corresponding inner surface plus the penetration and installation of fixing plug in order to possess the simple and convenient effect of assembly, moreover, for the assembly of combined heat sink and memory in an embodiment, it is only necessary to embed the memory directly to achieve the required locking and positioning function, and finally, the heat dissipating efficiency of the memory can then be enhanced.

Yet another purpose of the current invention is to provide an improved heat sink for memory wherein the outer surface of the two clamp pieces is installed with dented and bumped interleaved special marks, it is installed according to actually needed air flowing field direction in order to enhance heat convection and heat dissipating effect.

In order to help people understand the features of the current invention, it is described in the following order accompanies with the drawing:

### DETAILED DESCRIPTION OF THE PREFERRED EMBODIMENTS

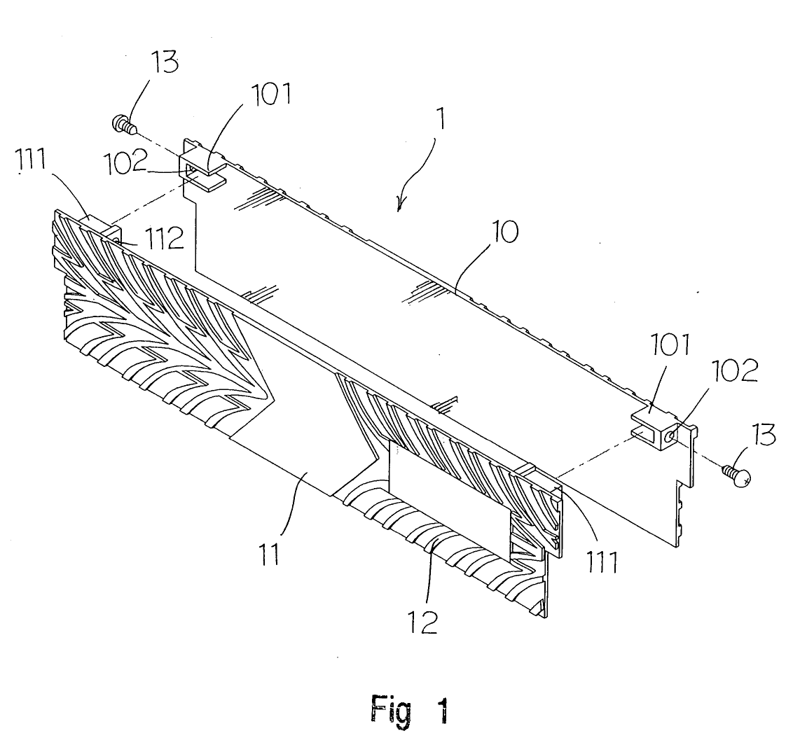

First, please refer to FIG. 1, it discloses the whole improved heat sink structure for memory for the current invention, the heat sink (1) comprising of: two clamp pieces of symmetrical design (10, 11) and the fixing plug (13) used to combine two clamp pieces (10, 11) wherein

The two clamp pieces (10, 11) adopt the design of symmetrical shape using heat conducting metal, dented and bumped interleaved special marks (12) are installed at its outer side surface, it can be changed according to the air flow field direction when it is practically assembled inside the mainframe in order to accelerate the convective effect and enhance the heat dissipating efficiency; moreover, at the two sides of the top edge of one side of the corresponding inner surface of the two clamp pieces (10, 11) are respectively installed with dented pivoting part (101) and protruding pivoting part (111), the dented and protruding pivoting parts (101, 111) are respectively installed with corresponding screw holes (102, 112), they can provide the positioning bases for the connection of the memory (2) and prevent two clamps (10, 11) get distorted or rotated outwards to an open status during the combination which might be detrimental to the combination and positioning of the memory (2), through the help of these two clamp pieces (10, 11) and through the penetration, installation and locking of fixing plug (13), an inverted U shape complete heat sink (1) structure can be easily formed, as shown in FIG. (2).

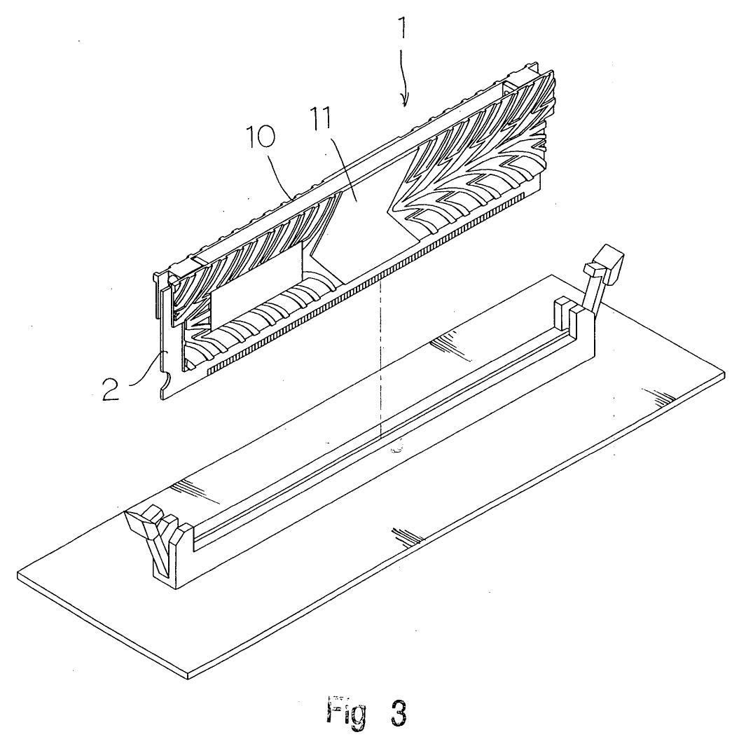

Please also refer to FIG. 3, when it is used practically in the assembly operation in the production line, a clamp piece (10) is placed first, the memory (2) is placed vertically, let the memory (2) touch the bottom of the dented pivoting part (101) to help accurate positioning of the memory (2), finally another clamp piece (11) is similarly combined vertically to let its protruding pivoting part (111) touch closely the corresponding dented pivoting part (101), meanwhile, through the penetration and installation of fixing plug (13) to complete the assembly, and let the memory (2) be accommodated and positioned through the limitation of two clamp pieces (10, 11) and their dented and protruding pivoting parts (101, 111); therefore, when memory (2) operates continuously for a long time, the heat it generated can thus be conducted to outer surface through heat conduction effect of the two clamp pieces (10, 11) in order to accelerate heat dissipating efficiency, the functions such as easy assembly, easy to use and fast heat dissipation can thus be achieved.

Since the heat sink of the current invention uses simplest structure and design to achieve fastest assembly effectiveness, it is thus very easy to be embodied, similarly, it is very easy and convenient to disassemble, especially the locking and positioning method of direct embedding of memory is far simpler than that of the prior art, there is no embodiment difficulty at all.

To summarize the above-mentioned, an improved heat sink for memory of the current invention can really achieve the expected purpose and function, it also meets the requirement for a patent application, we therefore submit this application, however, the above-mentioned is only a better embodiment of the current invention, it is not used to limit the application scope of the current invention, any equivalent change and modification without departing from the spirit of the claims of the current invention should still fall within the scope of the claims of the current invention.

### SPECIFIC DRAWING

(1) The representative figure of the current invention: FIG. 1.

(2) Brief descriptions of the component symbols of the representative drawing of the current invention.

| | | | |
|---|---|---|---|
| Heat sink | (1) | Clamp piece | (10) |
| Dented pivoting part | (101) | Screw hole | (102) |
| Clamp piece | (11) | Protruding pivoting part | (111) |
| Screw hole | (112) | Special mark | (12) |
| Fixing plug | (13) | | |

### BRIEF DESCRIPTION OF THE DRAWINGS

FIG. 1 is the decomposition drawing of one better embodiment of the current invention.

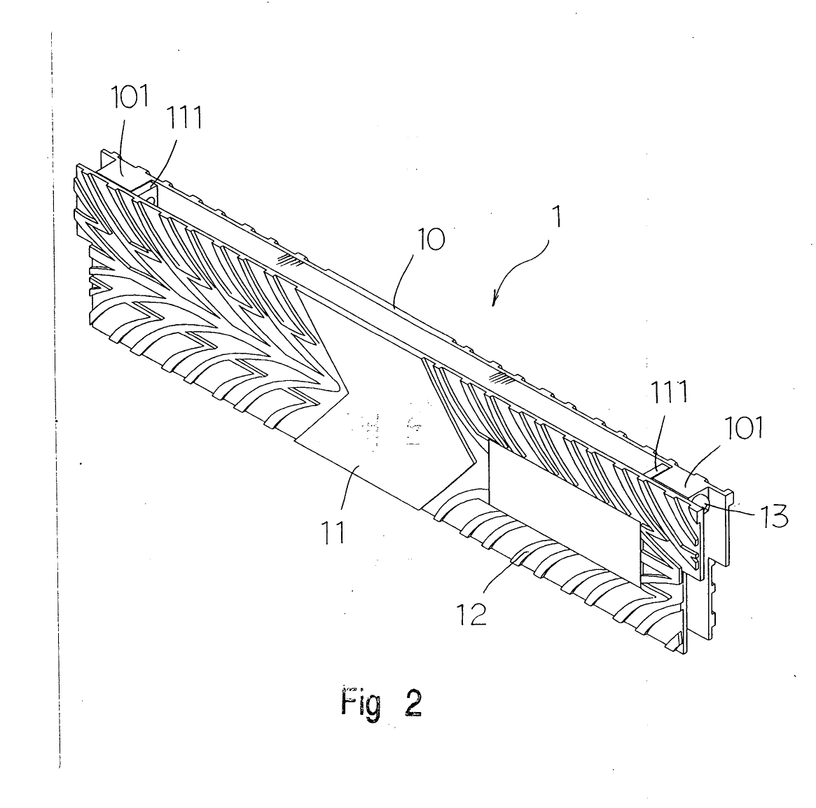

FIG. 2 is the assembly drawing of one better embodiment of the current invention.

FIG. 3 is the example illustration drawing of one better embodiment of the current invention.

### SYMBOL DESCRIPTIONS

| | | | |
|---|---|---|---|
| Heat sink | (1) | Clamp piece | (10) |
| Dented pivoting part | (101) | Screw hole | (102) |
| Clamp piece | (11) | Protruding pivoting part | (111) |
| Screw hole | (112) | Special mark | (12) |
| Fixing plug | (13) | Memory | (2) |

What is claimed is:

1. An improved heat sink for memory comprising of two symmetrical clamp pieces and fixing plug; having the following features:
at the two sides of the top edge of one side of the corresponding inner surface of the two clamp pieces are respectively installed with dented pivoting part and protruding pivoting part, the dented and protruding pivoting parts are respectively installed with corresponding screw holes (102, 112), they can provide the space for the penetration and installation of a fixing plug.

2. The improved heat sink for memory of claim 1 wherein the outer surfaces of the two clamp pieces are installed respectively with all kinds of dented and protruding interleaved special marks.
